(19) United States
(12) Patent Application Publication
(10) Pub. No.: US 2015/0064889 A1
(43) Pub. Date: Mar. 5, 2015

(54) Method for Dopant Implantation of FinFET Structures

(71) Applicant: IMEC VZW, Leuven (BE)

(72) Inventors: Vasile Paraschiv, Kessel-lo (BE); Gustaf Winroth, Ixelles (BE); Efrain Altamirano Sanchez, Kessel-lo (BE); Sabrina Locorotondo, Kontich (BE); Raja Athimulam, Heverlee (BE)

(73) Assignee: IMEC VZW, Leuven (BE)

(21) Appl. No.: 14/470,462

(22) Filed: Aug. 27, 2014

(30) Foreign Application Priority Data
Aug. 27, 2013 (EP) 13181803.1

(51) Int. Cl. H01L 21/027; H01L 21/033; H01L 21/266

(52) U.S. Cl. CPC H01L 21/0276; H01L 21/266; H01L 21/0337
USPC 438/514

(57) ABSTRACT

The present disclosure is related to a method for implanting dopant elements in a structure comprising a plurality of semiconductor fins separated by field dielectric areas. The method includes depositing an etch stop layer on the fins, depositing a BARC layer on the etch stop layer, depositing a resist layer on the BARC layer, removing a portion of the resist layer by lithography steps to thereby expose an area of the BARC layer, removing the BARC layer in the exposed area by a dry etch process using the remaining resist layer as a mask, implanting dopant elements into the fins present in the area, using the BARC and resist layers as a mask, and removing the remainder of the resist and BARC layers.

### CROSS-REFERENCE TO RELATED APPLICATION

This application claims priority to European Patent Application No. 13181803.1 filed on Aug. 27, 2013, the contents of which are hereby incorporated by reference.

### FIELD OF THE DISCLOSURE

The present disclosure is related to the production of integrated circuits (ICs) provided with fin-shaped structures.

### BACKGROUND

FinFET technology has been one of the main avenues for increasing the device density on an IC. The topography represented by the fin-structures however poses new challenges in various domains, notably in the area of lithography. Layers in an IC stack that need to be patterned on a stack with topography cannot easily be printed by photolithography without optical reflection control. In addition, for stringent control of critical dimensions (CDs), a planarising layer is needed for good profile control throughout the resist layer. A common planarising layer is a polymeric material that can be spin cast from solvent and that can be used simultaneously as a coating for reflection control. Such coatings are commonly called Bottom Anti-Reflective Coatings, or BARCs.

The BARC needs to be subsequently etched in order to open and transfer the patterns down to the substrate for further processing. A very common application is patterning ion implantation layers, where the photoresist and BARC together constitute the implantation mask. In this case, the BARC etch opening and over-etch, which clears the BARC around the fins, cannot be allowed to consume or damage the underlying topography.

These problems have become more prominent with the development of lithography from the 248 nm wavelength technology to the 193 nm wavelength technology, which is becoming the new norm due to the ever decreasing device dimensions. 193 nm lithography requires specific dimensions and materials of the resist and BARC layers, which can only be adequately etched by dry etching. This on the other hand limits the available etch chemistries suitable for removing the BARC without damaging the fins.

### SUMMARY OF THE DISCLOSURE

The disclosure is related to a method that helps to overcome one or more of the above-described problems. The method of the disclosure is disclosed in the appended claims.

The present disclosure is thus related to a method for implanting dopant elements in a structure comprising a plurality of semiconductor fins separated by field dielectric areas. The method includes depositing a BARC layer on the fins, depositing a resist layer on the BARC layer, removing a portion of the resist layer by lithography steps to thereby expose an area of the BARC layer, removing the BARC layer in the exposed area by a dry etch process using the remaining resist layer as a mask, implanting dopant elements into the fins present in the exposed area to thereby use the BARC and resist layers as a mask, and removing the remainder of the resist and BARC layers. The method also includes depositing an etch stop layer on the fins, in one example directly on the fins, before the steps of depositing a BARC layer and a resist layer. The etch stop layer protects the fins during the BARC removal step, so that the latter step can be performed using dry etch techniques that would otherwise have damaged the fins.

The etch stop layer may be a thin layer applied by Atomic Layer Deposition, the layer being conformal to the fin topography. According to an embodiment, the ion implantation can be done through the thin layer, thereby obviating the need for a removal step of the etch stop layer in the specific areas where the dopant implant is required. The BARC layer may be a planarizing layer, e.g., a layer that fills the spaces between the fins and forms a planar top surface. In another example, the BARC layer is a non-conformal BARC layer, e.g., a layer that forms a planar top surface without requiring a planarization step, such as a CMP step.

According to an embodiment, the thickness of the etch stop layer is between about 2 nm and about 5 nm. The lithography steps may be performed using 193 nm lithography technology.

According to an embodiment, the etch stop layer comprises a high-k dielectric material comprising Al, Ti, or Hf. The high-k dielectric material may be chosen from the group consisting of Al₂O₃, AN, TiN, or HfO₂.

### BRIEF DESCRIPTION OF THE FIGURES

FIGS. 1a to 1e illustrate the basic steps of the method according to one embodiment of the disclosure.

FIG. 2 illustrates an alternative method step.

### DETAILED DESCRIPTION OF THE DISCLOSURE

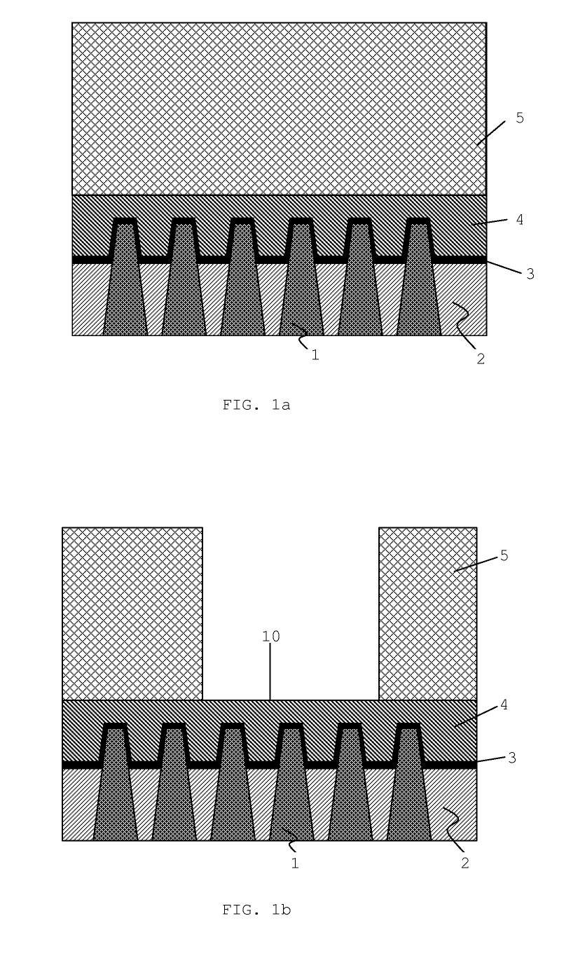

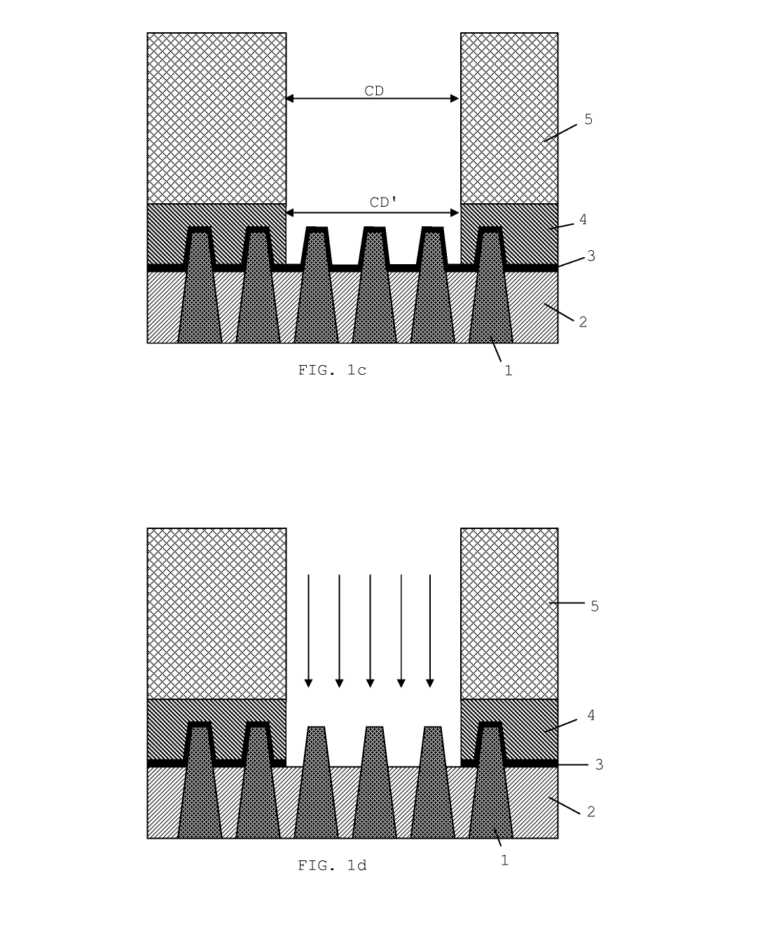

As shown in FIG. 1a, the method of the disclosure is applied on a fin-structure comprising a plurality of semiconductor fins 1 (e.g., silicon fins) arranged in an array of fins that are separated by a field dielectric 2 (e.g., SiO₂). These fins are built on an underlying support wafer, not shown in the drawings for the sake of simplicity. The manner in which this structure may be obtained is known as such to the skilled reader and is therefore not described here in detail. A dopant implantation step may be required in a restricted area of the fin array, for example, for the creation of HALO/HDD implants. This is what will be accomplished by the steps described hereafter.

In a first step, a thin dielectric layer 3 is deposited on the fins, such as directly onto the semiconductor fins. Although, it is not excluded that one or more further layers are present on the fins and that the thin layer 3 is deposited onto the one or more further layers. In the latter example, the one or more further layers may be regarded as part of the fins, with the thin dielectric layer being deposited directly on the fins. The thin dielectric layer may have a thickness that is suitable for forming a conformal layer, such as a layer that follows the topography of the fins, as illustrated in the figures. This layer may be produced by Atomic Layer Deposition (ALD), and will hereafter be referred to as the ‘ALD layer’, even though it is not excluded that the layer may be applied by other methods. As described in more detail hereinafter, the ALD layer may be configured as an etch stop layer in a further step of the method. The ALD layer 3 may be an Al₂O₃ layer, for example. According to an embodiment, the top width of the fins is in the order of about 10 nm (e.g., between about 5 nm and about 20 nm with the pitch of the array between about 30 nm and about 60 nm) and the thickness of the ALD-layer 3 is between about 2 nm and about 5 nm.

In the present example, a BARC layer 4 and a layer of photoresist 5 are subsequently deposited on top of the fin topography. The BARC layer 4 may be a planarizing layer, such that the BARC layer fills up the spaces between the fins and forms a flat upper surface. In this case, no additional planarizing step may be required, such as an additional Chemical Mechanical Polishing step. A planarizing BARC layer of this type, e.g., obtained by deposition of and forming a planar top surface without a planarization step, may also be referred to as a non-conformal or planar BARC layer. The thickness and material choice of the BARC are preferably suitable for lithography according to the 193 nm technology. For example, the BARC may be a layer of PMMA (Polymethylmethacrylate) between about 100 nm and about 180 nm thick, or any other material suitable for acting as a BARC, as known in the art, such as described in “New 193 nm Bottom Anti-Reflective Coating,” Nakayama et al., Proceedings of SPIE Vol. 5039 (2003), with a preference for the planar BARC types referred to in this document. The resist layer 5 may be formed of a chemically amplified methacrylate-based resist, with a thickness ranging between about 100 nm and about 400 nm. The BARC and resist may be deposited by a suitable method known in the art, for example, by a spin-on deposition followed by a baking step.

In the next step illustrated in FIG. 1b, an area 10 is defined, wherein a dopant implant is to be performed (in practice an array of such areas 10 may be defined, aligned with the fin topography). The definition of the area 10 may be performed by removing a portion of the resist 5. This can achieved by the steps of masking the resist, illuminating the exposed portions, developing the resist and removing the resist from the area in question. This leads to the structure shown in FIG. 1b, with an area 10 of the BARC 4 exposed, while the rest of the

BARC remains covered by resist material 5.

As illustrated in FIG. 1c, the BARC may then be removed in the area 10 by a plasma etch with a suitable etch chemistry that allows the BARC to be etched anisotropically, e.g., with essentially no lateral etching underneath the resist 5, so that the critical dimension (CD) is essentially maintained after removal of the BARC. As shown in FIG. 1c, CD is substantially equal to CD′. When the BARC is made of PMMA, this may be achieved by plasma etching in a fluorine based plasma with highly polymerizing gases like CH₂F₂ or CH₃F.

In the present example, the ALD layer 3 acts as an etch stop layer in the BARC removal etch process, e.g., the ALD layer ensures that the fins 1 are not attacked by the BARC removal etch. As discussed above, the ALD layer may be a conformal layer, such as a layer that follows the topography of the fins. Especially when the fin dimensions become very small (see dimensions given here above), a very thin ALD layer may be used that is nevertheless resistant to being etched in a dry etch process, such as a fluorine based plasma etch. When the BARC is a planarizing BARC, this resistance to the dry etch may be even more important as some areas of the BARC will require longer to be removed than others. The ALD layer furthermore may be configured to be removed selectively with respect to the underlying semiconductor and field oxide material. The present disclosure proves that it is possible to provide an etch stop layer that achieves at least some and perhaps all of these requirements. Example materials of the ALD layer that are suitable for this purpose are high K dielectrics, such as Al₂O₃, Hf-oxide, or AN.

According to the embodiment illustrated in FIG. 1d, the ALD layer is removed from the area 10, after which the dopant implant step (illustrated by the vertical arrows in FIG. 1d) is performed, using the resist 5 and BARC 4 as an implant mask so that dopants are implanted only in area 10 of the fin topography. After that, the resist and BARC are stripped (FIG. 1e). The remainder of the ALD layer 3 is then removed from the rest of the fin array. The removal of the ALD layer 3 from area 10 before dopant implantation, as well as, the removal of the remainder of the ALD layer after dopant implantation and resist+BARC strip may be performed, for example, by a diluted HF solution or by an isotropic dry etch process with high selectivity towards the fins 1 and the field dielectric areas 2.

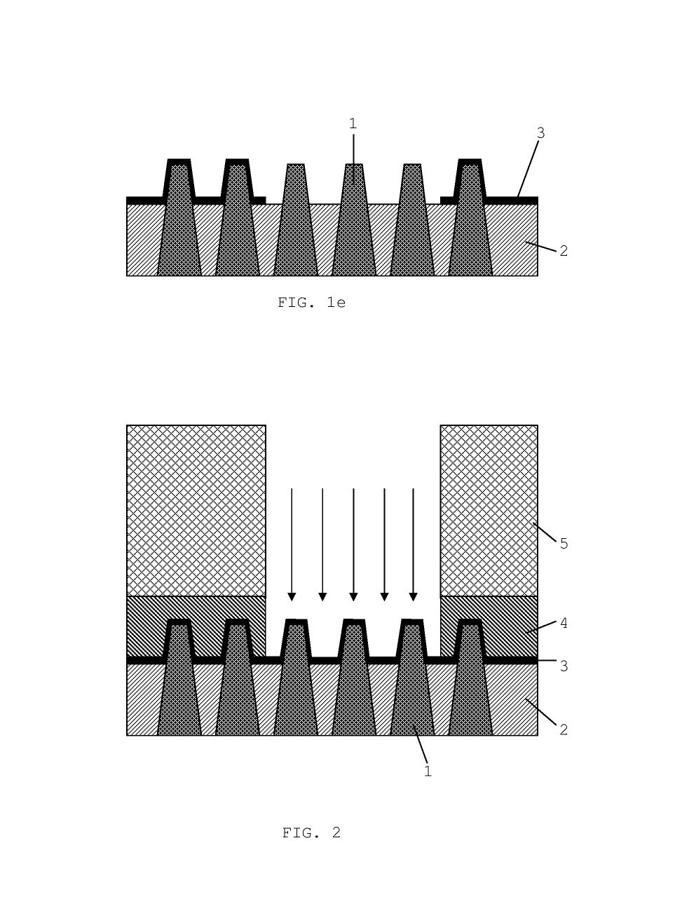

According to another embodiment (see FIG. 2), the dopant implant is performed without removing the ALD layer 3 from the area 10, such that dopant elements are implanted through the ALD layer 3. This may be possible when the ALD layer is sufficiently thin to allow dopant implantation through the layer. For example, this may be achieved by a 2 nm thick Al₂O₃ layer deposited on silicon fins. After the implant step, the resist and BARC may be stripped, and the ALD layer 3m removed from the totality of the fin-array (again e.g. by HF or dry etch).

### Example of Process Parameters

In one example, silicon bulk fin wafers with a 30 nm high topography and a 100 nm deep field oxide are used as substrates in the ALD process, where 5 nm Al₂O₃ is deposited conformally over the fins. In the example, the fin pitch is 45 nm and the fin width is 8 nm on top and 10 nm at the field oxide surface.

Further, in the present example, the BARC layer is a 30 nm thick layer of ARC95 (product name of material from company AMC) is spin cast at 2500 rpm, which corresponds to a 30 nm thickness on blanket Si-wafers. ARC95 is a planar or non-conformal type of BARC layer as defined above, and thus forms a layer with a flat upper surface without requiring a planarization step. There is a subsequent bake of 205° C. in order to cross-link the layer, such as to make it insoluble to the casting solvent. This may be necessary since the resist is spin cast on top from a similar solvent, e.g., an ester-like solvent. The resist (JSR ARX3500 from company JSR NV) is spin cast at 1500 rpm to a final thickness of 230 nm. There is a post-apply bake of 100° C. for 60 seconds. Both the BARC and resist spincasting, as well as, the post-apply bakes are performed sequentially in an automated program on an ACT 12 wafer track from Tokyo Electron Ltd (TEL™). After each bake step, the wafers are cooled down to ambient air temperature (22° C.) for at least 60 seconds.

The wafer track is interfaced with a lithographic scanner, such as a Twinscan™ XT1250D from ASML. The exposures are targeted to resolve a 200 nm wide space pattern in a 400 nm pitch line-space grating, which is aligned over the fin topography of the substrate (e.g., the width CD in FIG. 1c is 200 nm and an array with a pitch of 400 nm of such areas 10 is aligned with the fin topography). After exposure, the wafers are ported back to the same track for post-exposure bakes (130° C.) and development in a 0.262N TMAH (Tetramethylammonium hydroxide) puddle for 60 seconds.

The BARC etch is performed in a LAM Kiyo® 3C chamber using a Chlorine based chemistry, which clears out all the organic material (BARC) from the topography and completely exposes the Al₂O₃ in the trench.

The wafer is then implanted through the Al₂O₃ layer with Arsenic ions at a set kinetic energy of 2 keV in an Applied Materials Quantum®X ion implantation tool. The final dose is 1e15 cm².

The resist and BARC is then stripped in the LAM Kiyo® 3C chamber using an oxygen based chemistry. Once cleared from the organic residues of the resist and BARC, the Al₂O₃ can be easily removed selectively to the substrate by a wet process using a diluted HCl and ammonium peroxide solutions.

While the disclosure has been illustrated and described in detail in the drawings and foregoing description, such illustration and description are to be considered illustrative or exemplary and not restrictive. Other variations to the disclosed embodiments can be understood and effected by those skilled in the art in practicing the claimed disclosure, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to some advantage.

The foregoing description details certain embodiments of the disclosure. It will be appreciated, however, that no matter how detailed the foregoing appears in text, the disclosure may be practiced in many ways, and is therefore not limited to the embodiments disclosed. It should be noted that the use of particular terminology when describing certain features or aspects of the disclosure should not be taken to imply that the terminology is being re-defined herein to be restricted to include any specific characteristics of the features or aspects of the disclosure with which that terminology is associated.

Unless specifically specified, the description of a layer being deposited or produced ‘on’ another layer or substrate, includes the options of (i) the layer being produced or deposited directly on or in contact with the other layer or substrate, and (ii) the layer being produced on one or a stack of intermediate layers between the layer and the other layer or substrate.

1. A method for implanting dopant elements in a structure comprising a plurality of semiconductor fins separated by field dielectric areas, the method comprising:
depositing an etch stop layer on the fins;
depositing a BARC layer on the etch stop layer;
depositing a resist layer on the BARC layer removing a portion of the resist layer by lithography steps, thereby exposing an area of the BARC layer;
removing the BARC layer in the exposed area by a dry etch process using the remaining resist layer as a mask;
implanting dopant elements into the fins present in the area, using the BARC and resist layers as a mask; and
removing the remainder of the resist and BARC layers.

2. The method according to claim 1, wherein the BARC layer is a planarizing layer.

3. The method according to claim 2, wherein the BARC layer is a non-conformal BARC layer.

4. The method according to claim 1, wherein the etch stop layer is removed in the exposed area before the step of implanting dopant elements.

5. The method according to claim 1, wherein the etch stop layer is not removed in the exposed area before the step of implanting dopant elements, and wherein the dopant elements are implanted through the etch stop layer.

6. The method according to claim 1, wherein the etch stop layer is a conformal layer that follows the topography defined by the fins.

7. The method according to claim 6, wherein a thickness of the etch stop layer is between about 2 nm and about 5 nm.

8. The method according to claim 1, wherein the etch stop layer is deposited by atomic layer deposition (ALD).

9. The method according to claim 1, wherein the lithography steps are performed using 193 nm lithography technology.

10. The method according to claim 1, wherein the etch stop layer comprises a high-k dielectric material comprising Al, Ti, or Hf.

11. The method according to claim 10, wherein the high-k dielectric material is chosen from the group consisting of Al₂O₃, AlN, TiN, and HfO₂.
